(19) United States
(12) Patent Application Publication
(10) Pub. No.: US 2018/0237337 A1
(43) Pub. Date: Aug. 23, 2018

(54) SEALED DEVICES AND METHODS FOR MAKING THE SAME

(71) Applicant: CORNING INCORPORATED, CORNING, NY (US)

(72) Inventors: James Gregory Couillard, Ithaca, NY (US); David Francis Dawson-Elli, Dundee, NY (US); Stephan Lovovich Logunov, Corning, NY (US); Mark Alejandro Quesada, Horseheads, NY (US); Alexander Mikhailovich Streltsov, Corning, NY (US); Leonard Gerard Wamboldt, Sunderland, MA (US)

(21) Appl. No.: 15/752,183

(22) PCT Filed: Aug. 11, 2016
(86) PCT No.: PCT/US2016/046495

§ 371 Date: Feb. 12, 2018

Related U.S. Application Data
(60) Provisional application No. 62/204,122, filed on Aug. 12, 2015.
(60) Provisional application No. 62/214,548, filed on Sep. 4, 2015.
(60) Provisional application No. 62/249,691, filed on Nov. 2, 2015.

(51) Int. Cl. C03C 27/04; C03C 8/24; C04B 37/04

(52) U.S. Cl. CPC C03C 27/044; C03C 8/24; C04B 37/042; C04B 37/045; C04B 2237/10; H01L 33/486; C04B 2237/361; C04B 2237/365; C04B 2237/366; H01L 2933/0041; C04B 2237/343

(57) ABSTRACT

Disclosed herein are sealed devices comprising at least one cavity containing at least one quantum dot or at least one laser diode are also disclosed herein. The sealed devices can comprise a glass substrate sealed to an inorganic substrate, optionally via a sealing layer, the seal extending around the at least one cavity. Display and optical devices comprising such sealed devices are also disclosed herein, as well as methods for making such sealed devices.

### CROSS-REFERENCE TO RELATED APPLICATIONS

This application claims the benefit of priority under 35 U.S.C. § 119 of U.S. Provisional Application Ser. No. 62/249,691 filed on Nov. 2, 2015, U.S. Provisional Application Ser. No. 62/214,548 filed on Sep. 4, 2015 and U.S. Provisional Application Ser. No. 62/204,122 filed on Aug. 12, 2015, the contents of each of which are relied upon and incorporated herein by reference in their entireties.

### FIELD OF THE DISCLOSURE

The disclosure relates generally to sealed devices, and more particularly to sealed devices comprising quantum dots, laser diodes, light emitting diodes, or other light emitting structures, as well as display and optical devices comprising such sealed components.

### BACKGROUND

Sealed glass packages and casings are increasingly popular for application to electronics and other devices that may benefit from a hermetic environment for sustained operation. Exemplary devices which may benefit from hermetic packaging include televisions, sensors, optical devices, organic light emitting diode (OLED) displays, 3D inkjet printers, laser printers, solid-state lighting sources, and photovoltaic structures. For instance, displays comprising OLEDs or quantum dots (QDs) may call for sealed hermetic packages to prevent the possible decomposition of these materials at atmospheric conditions.

Glass, ceramic, and/or glass-ceramic substrates can be sealed by placing the substrates in a furnace, with or without an epoxy or other sealing material. However, the furnace typically operates at high processing temperatures which are unsuitable for many devices, such as OLEDs and QDs. Glass substrates can also be sealed using glass frit, e.g., by placing glass frit between the substrates and heating the frit with a laser or other heat source to seal the package. Frit-based sealants can include, for instance, glass materials ground to a particle size ranging typically from about 2 to 150 microns. The glass frit material can be mixed with a negative CTE material having a similar particle size to lower the mismatch of thermal expansion coefficients between substrates and the glass frit.

Glass frit materials typically have a glass transition temperature (T_{g}) greater than 450° C. and thus may require processing at elevated temperatures to form a hermetic seal. Such a high-temperature sealing process can be detrimental to temperature-sensitive workpieces. Further, the negative CTE inorganic fillers in the frit paste can negatively impact the transparency of the frit, resulting in an opaque seal. Accordingly, it would be advantageous to provide sealed devices which are both transparent and hermetic, as well as methods for forming such devices at lower temperatures suitable for encapsulating heat-sensitive workpieces.

### SUMMARY

The disclosure relates, in various embodiments, to sealed devices comprising a glass substrate comprising a first surface; an inorganic substrate comprising a second surface; a sealing layer in contact with at least a portion of the first surface and at least a portion of the second surface; and at least one seal bonding the glass substrate to the inorganic substrate via the sealing layer, wherein the inorganic substrate has a thermal conductivity of greater than about 2.5 W/m-K, wherein at least one of the first or second surfaces comprises at least one cavity containing at least one quantum dot and at least one LED component, and wherein the seal extends around the at least one cavity.

Sealed devices comprising laser diodes are also disclosed herein, the devices comprising a glass substrate comprising a first surface; an inorganic substrate comprising a second surface; a sealing layer in contact with at least a portion of the first surface and at least a portion of the second surface; and at least one seal bonding the glass substrate to the inorganic substrate via the sealing layer, wherein the inorganic substrate has a thermal conductivity of greater than about 2.5 W/m-K, wherein at least one of the first or second surfaces comprises at least one cavity containing at least one laser diode, and wherein the seal extends around the at least one cavity.

Further disclosed herein are sealed devices comprising a glass substrate comprising a first surface, a doped inorganic substrate comprising a second surface; and at least one seal bonding the glass substrate to the doped inorganic substrate, wherein the doped inorganic substrate comprises a thermal conductivity of greater than about 2.5 W/m-K and at least about 0.05 wt % of at least one dopant chosen from ZnO, SnO, SnO₂, or TiO₂. In some embodiments, the glass substrate may be bonded directly to the inorganic substrate or may be bonded by way of a sealing layer.

Methods for making such sealed devices are also disclosed, the methods comprising placing at least one quantum dot and at least one LED component in at least one cavity on a first surface of a glass substrate or a second surface of an inorganic substrate; positioning a sealing layer over at least a portion of the first surface or at least a portion of the second surface; bringing the first surface into contact with the second surface with the sealing layer positioned therebetween to form a sealing interface; and directing a laser beam operating at a predetermined wavelength onto the sealing interface to form a seal between the glass substrate and the inorganic substrate, the seal extending around the at least one cavity containing the at least one quantum dot and the at least one LED component, wherein the inorganic substrate has a thermal conductivity of greater than about 2.5 W/m-K.

Further disclosed herein are methods of making a sealed device comprising a laser diode, the methods comprising placing at least one laser diode in at least one cavity on a first surface of a glass substrate or a second surface of an inorganic substrate; positioning a sealing layer over at least a portion of the first surface or at least a portion of the second surface; bringing the first surface into contact with the second surface with the sealing layer positioned therebetween to form a sealing interface; and directing a laser beam operating at a predetermined wavelength onto the sealing interface to form a seal between the glass substrate and the inorganic substrate, the seal extending around the at least one cavity containing the at least one laser diode, wherein the inorganic substrate has a thermal conductivity of greater than about 2.5 W/m-K.

Additional methods disclosed herein include methods for making a sealed device, the methods comprising doping an inorganic substrate with at least one dopant absorbing at a predetermined wavelength; bringing a first surface of a glass substrate into contact with a second surface of the doped inorganic substrate to form a sealing interface; and directing a laser beam operating at the predetermined wavelength onto the sealing interface to form a seal between the glass substrate and the inorganic substrate, wherein the inorganic substrate has a thermal conductivity greater than about 2.5 W/m-K.

Still further disclosed herein are methods for making a sealed device, the methods comprising bringing a first surface of a glass substrate and a second surface of an inorganic substrate into contact with a sealing layer to form a sealing interface; and directing a laser beam operating at a predetermined wavelength onto the sealing interface to form a seal between the glass substrate and the inorganic substrate; wherein a difference between the CTE of the glass substrate and the CTE of the inorganic substrate is less than about 20×10⁻⁷/° C., and wherein the inorganic substrate has a thermal conductivity greater than about 2.5 W/m-K.

Additional features and advantages of the disclosure will be set forth in the detailed description which follows, and in part will be readily apparent to those skilled in the art from that description or recognized by practicing the methods as described herein, including the detailed description which follows, the claims, as well as the appended drawings.

It is to be understood that both the foregoing general description and the following detailed description present various embodiments of the disclosure, and are intended to provide an overview or framework for understanding the nature and character of the claims. The accompanying drawings are included to provide a further understanding of the disclosure, and are incorporated into and constitute a part of this specification. The drawings illustrate various embodiments of the disclosure and, together with the description, serve to explain the principles and operations of the disclosure.

### BRIEF DESCRIPTION OF THE DRAWINGS

The following detailed description can be further understood when read in conjunction with the following drawings in which, where possible, like numerals are used to refer to like elements, and:

FIG. 1 illustrates a cross-sectional view of a quantum dot film positioned adjacent a cavity comprising a light emitting diode (LED);

FIGS. 2A-C illustrate cross-sectional views of sealed devices according to certain embodiments of the disclosure;

FIG. 3 illustrates a cross-sectional view of a sealing layer disposed between two substrates according to embodiments of the disclosure;

FIG. 4A illustrates a cross-sectional view of a sealing layer frame disposed between two substrates according to further embodiments of the disclosure;

FIG. 4B illustrates a top view of a substrate and sealing layer frame according to various embodiments of the disclosure;

FIG. 5 illustrates a cross-sectional view of a sealed device according to additional embodiments of the disclosure;

FIG. 6 illustrates a cross-sectional view of a sealed device according to further embodiments of the disclosure; and

FIGS. 7 and 8 are graphical depictions of optical performance of some embodiments of the disclosure.

### DETAILED DESCRIPTION

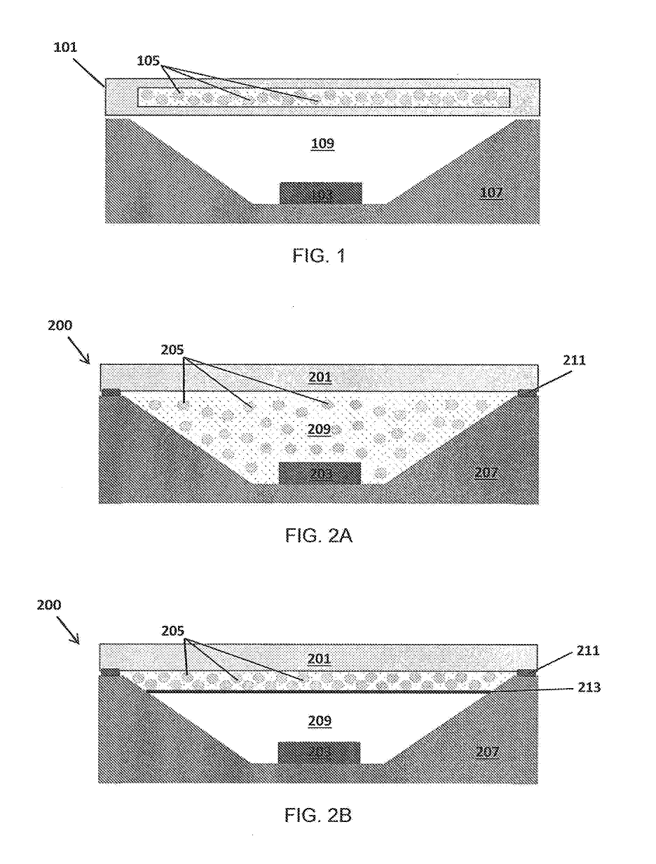

Disclosed herein are sealed devices comprising at least two substrates chosen from glass, glass-ceramic, and/or ceramic substrates. Exemplary sealed devices can include, for example, sealed devices encapsulating quantum dots, LEDs, laser diodes (LDs), and other light emitting structures. Display and optical devices comprising such sealed components are also disclosed herein. Displays such as televisions, computers, handheld devices, watches, and the like can comprise a backlight comprising quantum dots (QDs) as color converters. Exemplary optical devices can include but are not limited to sensors, watches, biosensors, and other devices configured to contain embodiments described herein. In some embodiments, QDs can be packaged, for example, in a glass tube, capillary, or sheet, e.g., a quantum dot enhancement film (QDEF) or encapsulated device such as a chiplet. Such films or devices can be filled with quantum dots, such as green and red emitting quantum dots, and can be sealed at both ends and/or around the periphery. Due to the temperature sensitivity of QDs, backlights using quantum dot material avoid direct contact between the quantum dot material and the light source, e.g., LED. Thus, as shown in FIG. 1, a sealed device 101, comprising a plurality of QDs or QD containing material 105, is often incorporated into the backlight stack as a separate component, e.g., placed in proximity to the LED 103, but kept at a sufficient distance to prevent the harsh conditions (e.g., temperatures up to about 140° C. and luminous flux up to about 100 W/cm²) from damaging the QDs or QD containing material 105. For example, the sealed device 101 can be placed in proximity to a first substrate 107 comprising one or more cavities 109 comprising an LED 103. In some instances, however, these sealed devices can result in significant material waste and/or can be complex to produce, e.g., QDEFs. Further, in the case of QDEFs, these films may also lack a good path for dissipating heat generated by color conversion. In some embodiments the sealed device 101 may include an upper substrate hermetically sealed to a lower substrate, both of which form an enclosure containing the QDs or QD containing material 105. This package or chiplet may then be sealed to the underlying first substrate 107. While not shown, such an embodiment may also be situated in the walls of the well formed in the first substrate 107 which contains the LED 103. In additional embodiments, one or more lenses (not shown), may be provided on a side of the chiplet or sealed device 101 opposite the LED 103.

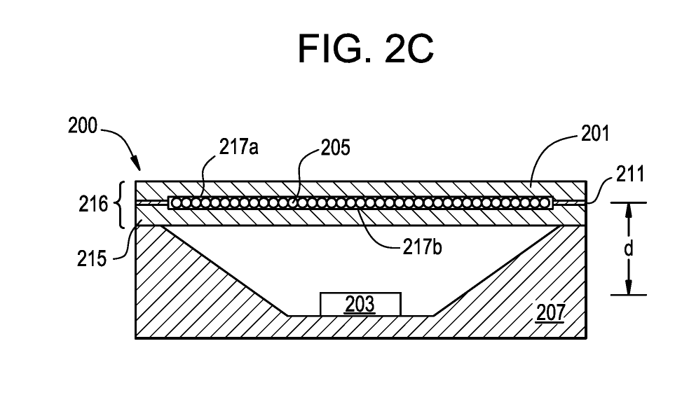

Various embodiments of the disclosure will now be discussed with reference to FIGS. 2-5, which illustrate exemplary sealed devices. The following general description is intended to provide an overview of the claimed devices, and various aspects will be more specifically discussed throughout the disclosure with reference to the non-limiting embodiments, these embodiments being interchangeable with one another within the context of the disclosure. Reference will be made throughout to a “first” substrate, a “glass” substrate, or a “first glass” substrate, these labels being used interchangeably to refer to the same substrates. Similarly, reference will be made throughout to a “second” substrate, an “inorganic” substrate, a “doped inorganic” substrate, or a “second inorganic” substrate, these labels being used interchangeably to refer to the same substrates.

Devices

Disclosed herein are sealed devices comprising a glass substrate comprising a first surface; an inorganic substrate comprising a second surface; a sealing layer in contact with at least a portion of the first surface and at least a portion of the second surface; and at least one seal bonding the glass substrate to the inorganic substrate via the sealing layer, wherein the inorganic substrate has a thermal conductivity of greater than about 2.5 W/m-K, wherein at least one of the first or second surfaces comprises at least one cavity containing at least one quantum dot and at least one LED component, and wherein the seal extends around the at least one cavity. Backlights and display devices comprising such sealed devices are also disclosed herein.

Cross-sectional views of two non-limiting embodiments of a sealed device 200 are illustrated in FIGS. 2A-B. The sealed device 200 comprises a first glass substrate 201 and a second inorganic substrate 207 comprising at least one cavity 209. The at least one cavity 209 can contain at least one quantum dot 205. The at least one cavity 209 can also contain at least one LED component 203. The first substrate 207 and second substrate 201 can be joined together by at least one seal 211, which can extend around the at least one cavity 209. Alternatively, the seal can extend around more than one cavity, such as a group of two or more cavities (not shown). In additional embodiments, one or more lenses (not shown), may be provided on a side of the first glass substrate 201 opposite the LED 203. The LED 203 may be any size in diameter or in length, for example, from about 100 μm to about 1 mm, from about 200 μm to about 900 μm, from about 300 μm to about 800 μm, from about 400 μm to about 700 μm, from about 350 μm to about 400 μm and any sub-ranges therebetween. The LED 203 may also provide a high or low flux, for example, for high flux purposes the LED 203 may emit 20 W/cm² or more. For low flux purposes, the LED 203 may emit less than 20 W/cm².

In the non-limiting embodiment depicted in FIG. 2A, the at least one LED component 203 can be in direct contact with the at least one quantum dot 205. As used herein the term “contact” is intended to denote direct physical contact or interaction between two listed elements, e.g., the quantum dot and LED component are able to physically interact with one another within the cavity. In the non-limiting embodiment depicted in FIG. 2B, the at least one LED component 203 and the at least one quantum dot 205 may be present in the same cavity, but are separated, e.g., by a separation barrier or film 213. By way of comparison, quantum dots in separate sealed capillaries or sheets, e.g., a QDEF as shown in FIG. 1, are not able to directly interact with the LED and are not located in the cavity with the LED.

In the non-limiting embodiment depicted in FIG. 2C, a sealed device 200 may include at least one LED component 203, a first substrate 201, a second substrate 207, and a third substrate 215. The first substrate 201 and third substrate 215 may form an hermetically sealed package or device 216 which forms an enclosed and encapsulated region containing the at least one quantum dot 205. In some embodiments the hermetically sealed package or device 216 will also include one or more films 217a, b such as, but not limited to, films that act as high pass filters and films that act as low pass filters or films that are provided to filter predetermined wavelengths of light. In some embodiments, the at least one LED component 203 can be spaced apart from the at least one quantum dot 205 by a predetermined distance “d”. In some embodiments the predetermined distance can be less than or equal to about 100 μm. In other embodiments, the predetermined distance is between about 50 μm and about 2 mm, between about 75 μm and about 500 μm, between about 90 μm and about 300 μm, and all subranges therebetween. In some embodiments, the predetermined distance is measured from a top surface of the LED component 203 to a midline of the enclosed and encapsulated region containing the at least one quantum dot 205. Of course, the predetermined distance may also be measured to any portion of the enclosed and encapsulated region containing the at least one quantum dot 205 such as but not limited to an upper surface of the third substrate 215 facing the at least one quantum dot 205, a lower surface of the first substrate 201 facing the at least one quantum dot 205, or a surface formed by any one of the films or filters 217a, b which may be present in the hermetically sealed package or device 216. In some embodiments, exemplary films include a filter 217a which prevents blue light from an exemplary LED component 203 from escaping the device 216 in one direction and/or another filter 217b which prevents red light (or another light emitted by excited quantum dot material) from escaping the device 216 in a second direction. For example, in some embodiments, the device 200 may comprise one or more LED components 203 contained in a well or other enclosure formed by the second substrate 207 and/or other substrates. An hermetically sealed package or device 216 in close proximity (e.g., a predetermined distance as discussed above) to the one or more LED components may be fixed to or sealed to the second substrate 207 and may comprise a first substrate 201 hermetically sealed to a third substrate 215 which forms an encapsulated region containing single wavelength quantum dot material 205 configured to emit light in an infrared wavelength, near-infrared wavelength, or in a predetermined spectrum (red) when excited by light emitted from the one or more LED components 203. The quantum dot material 205 can be spaced apart from the LED component 203 by a predetermined distance. In such an exemplary embodiment, a first filter 217a may be provided on the bottom (or top) surface of the first substrate 201 to filter blue light from emitting though the top surface of the device 200 and a second filter 217b may be provided on the top (or bottom) surface of the third substrate 215 to filter excited light from the quantum dot material from exiting the bottom surface of the third substrate 215. In additional embodiments, a filter 217c may be provided on the bottom surface of the second substrate 215 to filter blue light. These filters 217a, 217b, 217c, alone or in combination can in some embodiments include a plurality of thin film layers selected for their optical properties. In particular exemplary filters 217a, 217b, 217c can be designed to have high transmission for blue wavelengths to allow a blue LED light to emerge from a light guide plate adjacent the device 200. Such filters can also possess a high reflection for red and green wavelengths to reduce backreflection of light from the quantum dot material 205 back into the light guide plate.

One exemplary low pass filter 217a, 217b, 217c, includes a thin film stack made from multiple layers of high refractive index and low refractive index materials. In some embodiments, the stack includes an odd number of layers; in other embodiments, the stack includes an even number of layers. In some embodiments, the plural layers include 2 or more layers, 3 or more layers, 4 or more layers, 5 or more layers, 6 or more layers, 7 or more layers, 8 or more layers, 9 or more layers, 10 or more layers, 11 or more layers, 12 or more layers, 13 or more layers, 14 or more layers, 15 or more layers, 16 or more layers, 17 or more layers, 18 or more layers, 19 or more layers, 20 or more layers, 21 or more layers, 22 or more layers, 23 or more layers, 24 or more layers, 25 or more layers, 26 or more layers, 27 or more layers, 28 or more layers, 29 or more layers, and so on. In one embodiment, an exemplary filter comprises multiple alternating layers of a suitable high refractive index material and a suitable low refractive index material. Exemplary high refractive index materials include, but are not limited to, Nb₂O₅, Ta₂O₅, TiO₂, and compound oxides thereof. Exemplary low refractive index materials include, but are not limited to, SiO₂, ZrO₂, HfO₂, Bi₂O₃, La₂O₃, Al₂O₃, and compound oxides thereof. In one embodiment, an exemplary filter includes alternating layers of Nb₂O₅ and SiO₂ to a total thickness of approximately 1.8 μm which can be designed to pass light at 450 nm while reflecting 550 nm and 632 nm as provided in Table 1 below.

TABLE 1

| Layer | Material | Thickness (nm) |
|---|---|---|
| 21 | Nb₂O₅ | 80.19 |
| 20 | SiO₂ | 105.22 |
| 19 | Nb₂O₅ | 66.82 |
| 18 | SiO₂ | 105.22 |
| 17 | Nb₂O₅ | 66.82 |
| 16 | SiO₂ | 105.22 |
| 15 | Nb₂O₅ | 66.82 |
| 14 | SiO₂ | 105.22 |
| 13 | Nb₂O₅ | 66.82 |
| 12 | SiO₂ | 105.22 |
| 11 | Nb₂O₅ | 66.82 |
| 10 | SiO₂ | 105.22 |
| 9 | Nb₂O₅ | 66.82 |
| 8 | SiO₂ | 105.22 |
| 7 | Nb₂O₅ | 66.82 |
| 6 | SiO₂ | 105.22 |
| 5 | Nb₂O₅ | 66.82 |
| 4 | SiO₂ | 105.22 |
| 3 | Nb₂O₅ | 66.82 |
| 2 | SiO₂ | 105.22 |
| 1 | Nb₂O₅ | 80.19 |
| 0 | Glass | — |

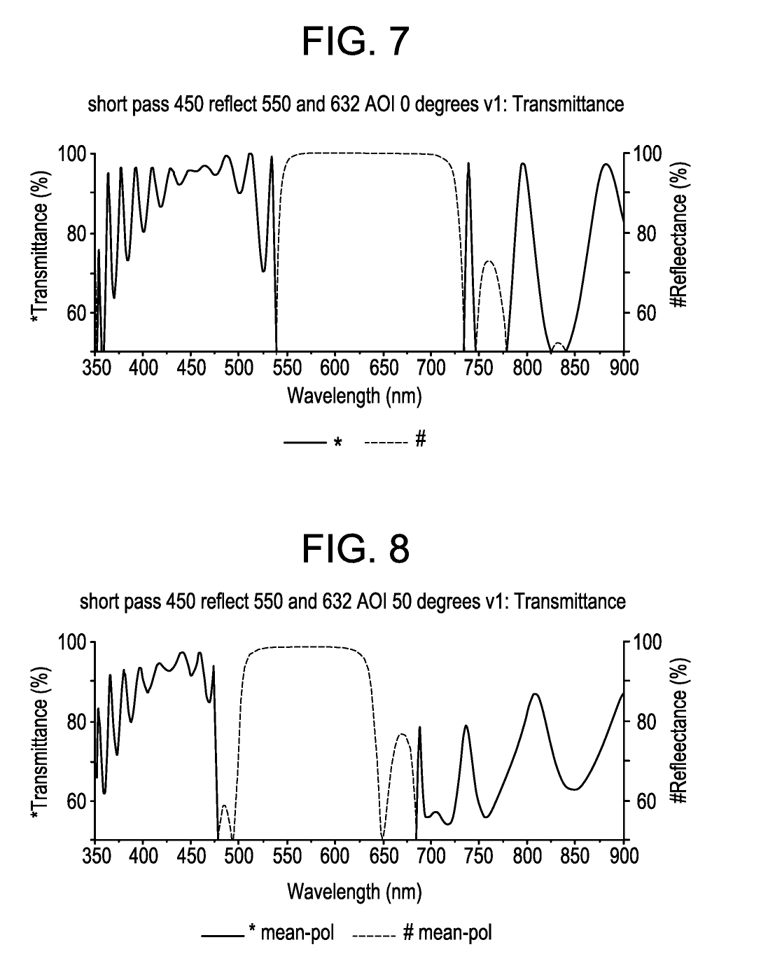

FIGS. 7 and 8 are graphical depictions of optical performance of some embodiments of the disclosure. With reference to FIG. 7, an optical performance of the filter from Table 1 at normal incidence is provided. It should be noted that the depicted embodiment provides a high transmission (solid line) at 450 nm and near 100% reflection (dashed line) over 550˜640 nm. With reference to FIG. 8, an optical performance of the filter from Table 1 at 50° incidence is provided. It should be noted that the depicted embodiment provides a transmission of blue light and reflection of red and green light even at high angles.

Exemplary filter embodiments can be used between a side lit or direct lit light guide plates and adjacent QD material, i.e., intermediate the QD material and light guide plates or as described above with reference to FIGS. 2B and 2C. For example, with continued reference to FIG. 2C, an exemplary filter 217c can improve the efficiency of directing light out of the package. In other embodiments, another location for the low pass filter can be on the cover glass (e.g., second substrate 215) such that the UV absorbing material is also the interference filter. Specifically, the material used as a high index material absorbs sufficient UV to enable the laser welding process described herein. These exemplary layers of material can be deposited by any number of thin film methods known in the art such as sputtering, plasma-enhanced chemical vapor deposition, and the like. The film or layer may be deposited directly onto the light guide plate or substrate or as a separate layer which is then attached by an optically clear adhesive. It was discovered that embodiments described herein having such filters (1) resulted in a higher forward light output, increasing overall brightness of the device 200 or light guide plate, (2) improved quantum dot conversion efficiency, enabling use of less quantum dot material, and (3) could rely on conventional thin film processing technology for ease of manufacture.

The first substrate 201, second substrate 207 and/or third substrate 215 can, in some embodiments, be chosen from glass substrates and may comprise any glass known in the art for use in display and other electronic devices. Suitable glasses can include, but are not limited to, aluminosilicate, alkali-aluminosilicate, borosilicate, alkali-borosilicate, aluminoborosilicate, alkali-aluminoborosilicate, and other suitable glasses. These substrates may, in various embodiments, be chemically strengthened and/or thermally tempered. Non-limiting examples of suitable commercially available substrates include EAGLE XG , Lotus™, Iris™, Willow®, and Gorilla® glasses from Corning Incorporated, to name a few. Glasses that have been chemically strengthened by ion exchange may be suitable as substrates according to some non-limiting embodiments.

According to various embodiments, the first, second, and/or third glass substrates 201, 207, 215 may have a compressive stress greater than about 100 MPa and a depth of layer of compressive stress (DOL) greater than about 10 microns. In further embodiments, the first, second and/or third glass substrate may have a compressive stress greater than about 500 MPa and a DOL greater than about 20 microns, or a compressive stress greater than about 700 MPa and a DOL greater than about 40 microns. In non-limiting embodiments, the first, second and/or third glass substrate can have a thickness of less than or equal to about 3 mm, for example, ranging from about 0.1 mm to about 2.5 mm, from about 0.3 mm to about 2 mm, from about 0.5 mm to about 1.5 mm, or from about 0.7 mm to about 1 mm, including all ranges and subranges therebetween.

The first, second and/or third glass substrates can, in various embodiments, be transparent or substantially transparent. As used herein, the term “transparent” is intended to denote that the substrate, at a thickness of approximately 1 mm, has a transmission of greater than about 80% in the visible region of the spectrum (400-700 nm). For instance, an exemplary transparent substrate may have greater than about 85% transmittance in the visible light range, such as greater than about 90%, or greater than about 95%, including all ranges and subranges therebetween. In certain embodiments, an exemplary glass substrate may have a transmittance of greater than about 50% in the ultraviolet (UV) region (200-400 nm), such as greater than about 55%, greater than about 60%, greater than about 65%, greater than about 70%, greater than about 75%, greater than about 80%, greater than about 85%, greater than about 90%, greater than about 95%, or greater than about 99% transmittance, including all ranges and subranges therebetween.

According to various embodiments, the second substrate 207 can be chosen from inorganic substrates, such as inorganic substrates having a thermal conductivity greater than that of glass. For example, suitable inorganic substrates may include those with a relatively high thermal conductivity, such as greater than about 2.5 W/m-K (e.g., greater than about 2.6, 3, 5, 7.5, 10, 15, 20, 25, 30, 40, 50, 60, 70, 80, 90, or 100 W/m-K), for instance, ranging from about 2.5 W/m-K to about 100 W/m-K, including all ranges and subranges therebetween. In some embodiments, the thermal conductivity of the inorganic substrate can be greater than 100 W/m-K, such as ranging from about 100 W/m-K to about 300 W/m-K (e.g., greater than about 100, 110, 120, 130, 140, 150, 160, 170, 180, 190, 200, 210, 220, 230, 240, 250, 260, 270, 280, 290, or 300 W/m-K), including all ranges and subranges therebetween.

According to various embodiments, the inorganic substrate can comprise a ceramic substrate, which can include ceramic or glass-ceramic substrates. In a non-limiting embodiment, the second substrate 207 can comprise aluminum nitride, aluminum oxide, beryllium oxide, boron nitride, or silicon carbide, to name a few. The thickness of the inorganic substrate can range, in certain embodiments, from about 0.1 mm to about 3 mm, such as from about 0.2 mm to about 2.5 mm, from about 0.3 mm to about 2 mm, from about 0.4 mm to about 1.5 mm, from about 0.5 mm to about 1 mm, from about 0.6 mm to about 0.9 mm, or from about 0.7 mm to about 0.8 mm, including all ranges and subranges therebetween. In additional embodiments, the inorganic substrate may have little or no absorption at a given laser operating wavelength, e.g., at UV wavelengths (200-400nm), or at visible wavelengths (400-700nm). For instance, the second inorganic substrate may absorb less than about 10% at the laser's operating wavelength, such as less than about 5%, less than about 3%, less than about 2%, or less than about 1% absorption, e.g., from about 1% to about 10%. At visible wavelengths the inorganic substrate may, in some embodiments, be transparent or scattering.

In still further embodiments, the second inorganic substrate may be doped with at least one dopant capable of absorbing light at a predetermined wavelength, e.g., at the predetermined operating wavelength of a laser. Dopants can include, for example, ZnO, SnO, SnO₂, TiO₂, and the like. In some embodiments, the dopant can be chosen from compounds absorbing at UV wavelengths (200-400 nm). The dopant can be incorporated into the inorganic substrates in an amount sufficient to induce absorption of the inorganic substrate at the predetermined wavelength. For instance, the dopant can be incorporated into the inorganic substrate at a concentration of greater than about 0.05 wt % (500 ppm), for example, ranging from about 500 ppm to about 10⁶ ppm. In some embodiments, the dopant concentration can be greater than about 0.5 wt %, greater than about 1 wt %, greater than about 2 wt %, greater than about 3 wt %, greater than about 4 wt %, greater than about 5 wt %, greater than about 6 wt %, greater than about 7 wt %, greater than about 8 wt %, greater than about 9 wt %, or greater than about 10 wt %, including all ranges and subranges therebetween. According to additional embodiments, the dopant may have a concentration greater than about 10 wt %, e.g., about 20 wt %, 30 wt %, 40 wt %, 50 wt %, 60 wt %, 70 wt %, 80 wt %, or 90 wt %, including all ranges and subranges therebetween. In further embodiments, the doped inorganic substrate may comprise about 100% dopant, e.g., in the case of a ZnO ceramic substrate.

According to various embodiments, the first, second and/or third substrates may be chosen such that the coefficients of thermal expansion (CTEs) of the substrates are substantially similar. For example, the CTE of the third or second substrate can be within about 50% of the CTE of the first substrate, such as within about 40%, within about 30%, within about 20%, within about 15%, within about 10%, or within about 5% of the CTE of the first substrate. By way of a non-limiting example, the CTE of the first glass substrate (at a temperature ranging from about 25-400° C.) can range from about 30×10⁻⁷/° C. to about 90×10⁻⁷/° C., such as from about 40×10⁻⁷/° C. to about 80×10⁻⁷/° C., or from about 50×10⁻⁷/° C. to about 60×10⁻⁷/° C. (such as about 30, 35, 40, 45, 50, 55, 60, 65, 70, 75, 80, 85, or 90×10⁻⁷/° C.), including all ranges and subranges therebetween. According to non-limiting embodiments, the glass substrates can be Corning® Gorilla® glass having a CTE ranging from about 75 to about 85×10⁻⁷/° C., or Corning® EAGLE XG®, Lotus™, or Willow® glasses having a CTE ranging from about 30 to about 50×10⁻⁷/° C. The second substrate can comprise an inorganic, e.g., ceramic or glass-ceramic substrate, having a CTE (at a temperature ranging from about 25-400° C.) ranging from about 20×10⁻⁷/° C. to about 100×10⁻⁷/° C., such as from about 30×10⁻⁷/° C. to about 80×10⁻⁷/° C., from about 40×10⁻⁷/° C. to about 70×10⁻⁷/° C., or from about 50×10⁻⁷/° C. to about 60×10⁻⁷/° C. (such as about 20, 25, 30, 35, 40, 45, 50, 55, 60, 65, 70, 75, 80, 85, 90, 95, or 100×10⁻⁷/° C.), including all ranges and subranges therebetween.

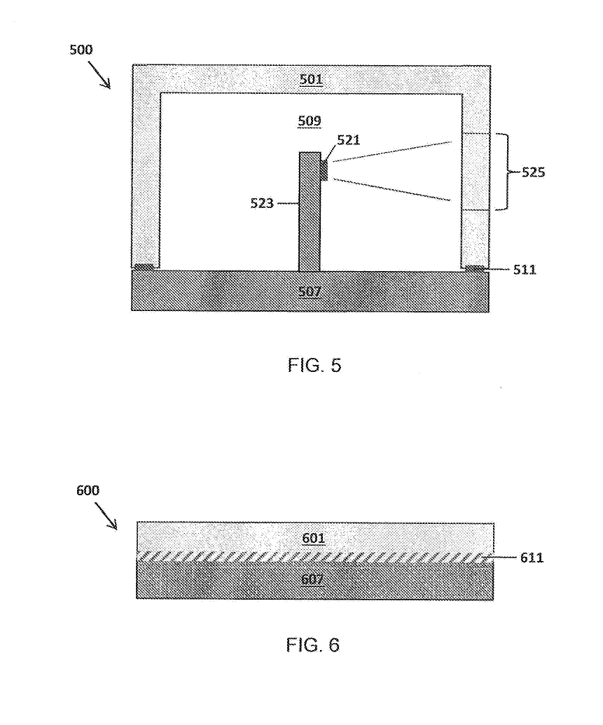

While FIGS. 2A-C depict the at least one cavity 209 as having a trapezoidal cross-section, it is to be understood that the cavities can have any given shape or size, as desired for a given application. For example, the cavities can have a square, cylindrical, rectangular, semi-circular, or semi-elliptical cross-section, or an irregular cross-section, to name a few. It is also possible for the surface of the first substrate 201 or third substrate 215 to comprise at least one cavity 209 (see, e.g., FIGS. 5 and 2C), or for both the first or third and second substrates to comprise cavities. Alternatively, or additionally, cavities in the first or second substrates can be filled with a material that is transparent at one or both of visible wavelengths or LED operating wavelengths.

Moreover, while FIGS. 2A-B depict a sealed device comprising a single cavity 209 sealed devices comprising a plurality or array of cavities are also intended to fall within the scope of the disclosure. For example, the sealed device can comprise any number of cavities 209, which can be arranged and/or spaced apart in any desired fashion including regular and irregular patterns. Furthermore, while the single cavity 209 in FIGS. 2A-B comprises both quantum dots and an LED component, it is to be understood that this depiction is not limiting. Embodiments in which one or more cavities do not comprise quantum dots and/or LED components are also envisioned (see, e.g., FIG. 2C). Embodiments in which one or more cavities comprise a plurality of LED components and/or quantum dots are also envisioned. Moreover, it is not required that each cavity comprise the same number or amount of quantum dots and/or LED components, it being possible for this amount to vary from cavity to cavity and for some cavities to comprise no quantum dots and/or LED components.

The at least one cavity 209 can have any given depth, which can be chosen as appropriate, e.g., for the type and/or shape and/or amount of the item (e.g., QD, LED, and/or LD) to be encapsulated in the cavity. By way of non-limiting embodiment, the at least one cavity 209 can extend into the first and/or second substrates to a depth of less than about 1 mm, such as less than about 0.5 mm, less than about 0.4 mm, less than about 0.3 mm, less than about 0.2 mm, less than about 0.1 mm, less than about 0.05 mm, less than about 0.02 mm, or less than about 0.01 mm, including all ranges and subranges therebetween, such as ranging from about 0.01 mm to about 1 mm. It is also envisioned that an array of cavities can be used, each cavity having the same or a different depths, the same or a different shapes, and/or the same or a different sizes, as compared to the other cavities in the array.

The at least one cavity 209 can, in some embodiments, comprise at least one quantum dot 205. Quantum dots can have varying shapes and/or sizes depending on the desired wavelength of emitted light. For example, the frequency of emitted light may increase as the size of the quantum dot decreases, e.g., the color of the emitted light can shift from red to blue as the size of the quantum dot decreases. When irradiated with blue, UV, or near-UV light, a quantum dot may convert the light into longer red, yellow, green, or blue wavelengths. According to various embodiments, the quantum dot can be chosen from red and green quantum dots, emitting in the red and green wavelengths when irradiated with blue, UV, or near-UV light. For instance, the LED component can emit blue light (approximately 450-490 nm), UV light (approximately 200-400 nm), or near-UV light (approximately 300-450nm).

Additionally, it is possible that the at least one cavity can comprise the same or different types of quantum dots, e.g., quantum dots emitting different wavelengths. For example, in some embodiments, a cavity can comprise quantum dots emitting both green and red wavelengths, to produce a red-green-blue (RGB) spectrum in the cavity. However, according to other embodiments, it is possible for an individual cavity to comprise only quantum dots emitting the same wavelength, such as a cavity comprising only green quantum dots or a cavity comprising only red quantum dots. For instance, the sealed device can comprise an array of cavities, in which approximately one-third of the cavities may be filled with green quantum dots and approximately one-third of the cavities may be filled with red quantum dots, while approximately one-third of the cavities may remain empty (so as to emit blue light). Using such a configuration, the entire array can produce the RGB spectrum, while also providing dynamic dimming for each individual color.

Of course it is to be understood that cavities containing any type, color, or amount of quantum dots in any ratio are possible and envisioned as falling within the scope of the disclosure. It is within the ability of one skilled in the art to choose the configuration of the cavity or cavities and the types and amounts of quantum dots to place in each cavity to achieve a desired effect. Moreover, although the devices herein are discussed in terms of red and green quantum dots for display devices, it is to be understood that any type of quantum dot can be used, which can emit any wavelength of light including, but not limited to, red, orange, yellow, green, blue, or any other color in the visible spectrum (e.g., 400-700nm).

Exemplary quantum dots can have various shapes. Examples of the shape of a quantum dot include, but are not limited to, sphere, rod, disk, tetrapod, other shapes, and/or mixtures thereof. Exemplary quantum dots may also be contained in a polymer resin such as, but not limited to, acrylate or another suitable polymer or monomer. Such exemplary resins may also include suitable scattering particles including, but not limited to, TiO₂ or the like.

In certain embodiments, quantum dots comprise inorganic semiconductor material which permits the combination of the soluble nature and processability of polymers with the high efficiency and stability of inorganic semiconductors. Inorganic semiconductor quantum dots are typically more stable in the presence of water vapor and oxygen than their organic semiconductor counterparts. As discussed above, because of their quantum-confined emissive properties, their luminescence can be extremely narrow-band and can yield highly saturated color emission, characterized by a single Gaussian spectrum. Because the nanocrystal diameter controls the quantum dot optical band gap, the fine tuning of absorption and emission wavelength can be achieved through synthesis and structure change.

In certain embodiments, inorganic semiconductor nanocrystal quantum dots comprise Group IV elements, Group II-VI compounds, Group II-V compounds, Group III-VI compounds, Group III-V compounds, Group IV-VI compounds, Group I-III-VI compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, alloys thereof, and/or mixtures thereof, including ternary and quaternary alloys and/or mixtures.

In certain embodiments a quantum dot can include a shell over at least a portion of a surface of the quantum dot. This structure is referred to as a core-shell structure. The shell can comprise an inorganic material, more preferably an inorganic semiconductor material, An inorganic shell can passivate surface electronic states to a far greater extent than organic capping groups. Examples of inorganic semiconductor materials for use in a shell include, but are not limited to, Group IV elements, Group II-VI compounds, Group II-V compounds, Group -VI compounds, Group III-V compounds, Group IV-VI compounds, Group compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, alloys thereof, and/or mixtures thereof, including ternary and quaternary alloys and/or mixtures.

In some embodiments, quantum dot materials can include II-VI semiconductors, including CdSe, CdS, and CdTe, and can be made to emit across the entire visible spectrum with narrow size distributions and high emission quantum efficiencies. For example, roughly 2 nm diameter CdSe quantum dots emit in the blue while 8 nm diameter particles emit in the red. Changing the quantum dot composition by substituting other semiconductor materials with a different band gap into the synthesis alters the region of the electromagnetic spectrum in which the quantum dot emission can be tuned. In other embodiments, the quantum dot materials are cadmium-free. Examples of cadmium-free quantum dot materials include InP and InₓGaₓ₋₁P. In an example of one approach for preparing InₓGaₓ₋₁P, InP can be doped with a small amount of Ga to shift the band gap to higher energies in order to access wavelengths slightly bluer than yellow/green. In an example of another approach for preparing this ternary material, GaP can be doped with In to access wavelengths redder than deep blue. InP has a direct bulk band gap of 1.27 eV, which can be tuned beyond 2 eV with Ga doping. Quantum dot materials comprising InP alone can provide tunable emission from yellow/green to deep red; the addition of a small amount of Ga to InP can facilitate tuning the emission down into the deep green/aqua green. Quantum dot materials comprising InₓGaₓ₋₁P (0<x<1) can provide light emission that is tunable over at least a large portion of, if not the entire, visible spectrum. InP/ZnSeS core-shell quantum dots can be tuned from deep red to yellow with efficiencies as high as 70%. For creation of high CRI white QD-LED emitters, InP/ZnSeS can be utilized to address the red to yellow/green portion of the visible spectrum and InₓGaₓ₋₁P will provide deep green to aqua-green emission.

In some embodiments, e.g., see FIGS. 2A, 2B and/or 2C, the quantum dot materials can provide a tunable emission in a predetermined spectrum. For example, exemplary quantum dot materials may be selected such that emission therefrom is only in single spectrum, i.e., single wavelength quantum dot material, such as but not limited to the red spectrum, e.g., from about 620 nm to about 750 nm. Of course, exemplary single wavelength quantum dot materials may be selected such that other spectrum (e.g., violet 308-450 nm, blue 450-495 nm, green 495-570 nm, yellow 570-590 nm, and orange 590-620 nm) are emitted when excited by a nearby light source such as the at least one LED component 203. In other embodiments, the quantum dot materials can provide a tunable emission in another spectrum such as but not limited to the infrared spectrum, e.g., from 700 nm to 1 mm, or the ultraviolet spectrum, e.g., from 10 nm to 380 nm.

A first surface of the first substrate 201 and a second surface of the second substrate 207 can be joined by a seal or weld 211. The seal 211 can extend around the at least one cavity 209, thereby sealing the workpiece within the cavity. For example, as shown in FIGS. 2A-B the seal can encapsulate the at least one quantum dot 205 and the at least one LED component 203 in the same cavity. In the case of multiple cavities, the seal can extend around a single cavity, e.g., separating each cavity from the other cavities in the array to create one or more discrete sealed regions or pockets, or the seal can extend around more than one cavity, e.g., a group of two or more cavities, such as three, four, five, ten, or more cavities and so forth. It is also possible for the sealed device to comprise one or more cavities that may not be sealed, as desired, for example, in the case of a cavity devoid of an LED and/or quantum dots. Thus, it is to be understood that various cavities can be empty or otherwise free of quantum dots and/or LEDs, these empty cavities thus being sealed or unsealed as appropriate or desired. In some embodiments, the seal 211 can comprise a glass-to-glass seal, a glass-to-glass-ceramic seal, or a glass-to-ceramic seal as described in co-pending U.S. application Ser. Nos. 13/777,584; 13/891,291; 14/270,828; and 14/271,797, all of which are incorporated herein by reference in their entireties.

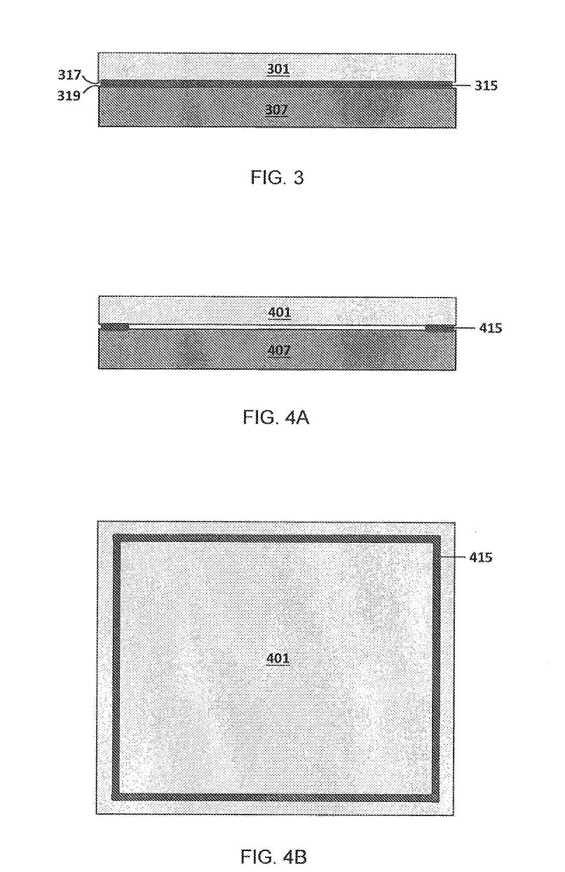

In other non-limiting embodiments, the device can comprise a sealing layer disposed between and connecting the first and second substrates. For example, as shown in FIG. 3, the sealing material or layer 315 can contact at least a portion of a first surface 317 of the first substrate 301 and at least a portion of a second surface 319 of the second substrate 307. The sealing layer 315 can be chosen, for example, from glass compositions having an absorption of greater than about 10% at the predetermined laser operating wavelength and/or a relatively low glass transition temperature (T_{g}). According to various embodiments, the sealing layer can be chosen from borate glasses, phosphate glasses tellurite glasses, and chalcogenide glasses, for instance, tin phosphates, tin fluorophosphates, and tin fluoroborates.

In general, suitable sealing layer materials can include low T_{g} glasses and suitably reactive oxides of copper or tin. By way of non-limiting example, the sealing layer can comprise a glass with a T_{g} of less than or equal to about 400° C., such as less than or equal to about 350° C., about 300° C., about 250° C., or about 200° C., including all ranges and subranges therebetween, such as ranging from about 200° C. to about 400° C. Suitable sealing layers and methods are disclosed, for instance, in U.S. patent application Nos. 13/777,584; 13/891,291; 14/270,828; and 14/271,797, all of which are incorporated herein by reference in their entireties.

The thickness of the sealing layer 315 can vary depending on the application and, in certain embodiments, can range from about 0.1 microns to about 10 microns, such as less than about 5 microns, less than about 3 microns, less than about 2 microns, less than about 1 micron, less than about 0.5 microns, or less than about 0.2 microns, including all ranges and subranges therebetween. The sealing layer 315 can have, in various embodiments, an absorption at the laser's operating wavelength (at room temperature) of greater than about 10%, greater than about 15%, greater than about 20%, greater than about 25%, greater than about 30%, greater than about 35%, greater than about 40%, greater than about 45%, or greater than about 50%, including all ranges and subranges therebetween, such as from about 10% to about 50%. For example, the sealing layer can be absorbing at UV wavelengths (200-400 nm), e.g., having an absorption of greater than about 10%. In some embodiments, the sealing layer can be transparent or substantially transparent to visible light, e.g., having a transmission of greater than about 80% in the visible region of the spectrum (400-700 nm).

As shown in FIG. 3, the sealing layer 315 can comprise a continuous sheet or layer between the first and second substrates 301, 307. For instance, the sealing layer 315 can be overlaid onto the first surface 317 or second surface 319 such that the sealing layer covers the at least one cavity (not shown). In such embodiments, the sealing layer 315 may be substantially transparent at visible wavelengths and absorbing at UV wavelengths (or any other predetermined laser operating wavelength). Alternatively, as depicted in FIGS. 4A-B, the sealing layer 415 can be provided such that it forms a frame around the cavity (not shown). The sealing layer can be applied to the first substrate 401 (as shown in FIG. 4B) or the second substrate 407 (not shown in FIG. 4B) in any desired shape or pattern. In such embodiments, the sealing layer 415 can be substantially transparent or absorbing at visible wavelengths and/or substantially transparent or absorbing at UV wavelengths (or any other predetermined laser operating wavelength). For example, the laser can be chosen to operate at any wavelength at which the sealing layer is absorbing and the first glass substrate is non-absorbing. Of course, the sealing layer 315, 415 can have any shape as desired fora particular application depending, e.g., on the substrate and/or cavity shape.

The seal 211 between the first and second substrates as depicted in FIGS. 2A-B can be formed by way of the sealing layer 315, 415 as depicted in FIGS. 3-4. For instance, a laser beam operating at a given wavelength can be directed at the sealing layer (or sealing interface) to form a seal or weld between the two substrates. Without wishing to be bound by theory, it is believed that absorption of light from the laser beam by the sealing layer and induced transient absorption by the first and/or second substrates can cause localized heating (e.g., to a temperature close to the T_{g} of the first substrate) and melting of the sealing layer and/or glass substrate to form a bond between the two substrates. According to various embodiments, the seal or weld 211 can have a width ranging from about 10 micron to about 300 microns, such as from about 25 microns to about 250 microns, from about 50 microns to about 200 microns, or from about 100 microns to about 150 microns, including all ranges and subranges therebetween.

The first and second substrates can, in various embodiments be sealed together as disclosed herein, to produce a seal or weld around the at least one cavity. In certain embodiments, the seal or weld may be a hermetic seal, e.g., forming one or more air-tight and/or waterproof pockets in the device. For example, at least one cavity can be hermetically sealed such that the cavity is impervious or substantially impervious to water, moisture, air, and/or other contaminants. By way of non-limiting example, a hermetic seal can be configured to limit the transpiration (diffusion) of oxygen to less than about 10⁻² cm³/m²/day (e.g., less than about 10⁻³/cm³/m²/day), and limit transpiration of water to about 10⁻² g/m²/day (e.g., less than about 10⁻³, 10⁻⁴, 10⁻⁵, or 10⁻⁶ g/m²/day). In various embodiments, a hermetic seal can substantially prevent water, moisture, and/or air from contacting the components protected by the hermetic seal.

According to certain aspects, the total thickness of the sealed device can be less than about 6 mm, such as less than about 5 mm, less than about 4 mm, less than about 3 mm, less than about 2 mm, less than about 1.5 mm, less than about 1 mm, or less than about 0.5 mm, including all ranges and subranges therebetween. For example, the thickness of the sealed device can range from about 0.3 mm to about 3 mm, such as from about 0.5 mm to about 2.5 mm, or from about 1 mm to about 2 mm, including all ranges and subranges therebetween.

The sealed devices disclosed herein may be used in various display devices or display components including, but not limited to backlights or backlit displays such as televisions, computer monitors, handheld devices, and the like, which can comprise various additional components. The sealed devices disclosed herein can also be used as illuminating devices, such as luminaires and solid state lighting applications. For example, a sealed device comprising quantum dots in contact with at least one LED die can be used for general illumination, e.g. mimicking the broadband output of the sun. Such lighting devices can comprise, for example, quantum dots of various sizes emitting at various wavelengths, such as wavelengths ranging from 400-700 nm.

Also disclosed herein are sealed devices comprising laser diodes, the devices comprising a glass substrate comprising a first surface; an inorganic substrate comprising a second surface; a sealing layer in contact with at least a portion of the first surface and at least a portion of the second surface; and at least one seal bonding the glass substrate to the inorganic substrate via the sealing layer, wherein the inorganic substrate has a thermal conductivity of at least 2.5 W/m-K, wherein at least one of the first or second surfaces comprises at least one cavity containing at least one laser diode, and wherein the seal extends around the at least one cavity. Hermetically packaged laser diodes can be useful in optical devices, printers, and the like.

Referring to FIG. 5, an exemplary sealed device 500 can comprise a first glass substrate 501 and a second inorganic substrate 507 sealed together via seal 511 to form at least one cavity 509. A laser diode 521 or other light emitting structure can be encapsulated in the cavity, optionally on a support 523. The support 523 can be used, in some embodiments, to adjust the height of the laser diode 521 within the sealed package as desired to emit light through a predetermined region or window 525 in the first glass substrate 501. Exemplary laser diodes can include semiconductor materials such as gallium nitride, gallium arsenide, aluminum gallium arsenide, gallium antimonide, and indium phosphide, to name a few. Laser diodes can emit light having any wavelength, such as visible (˜400-700 nm) and infrared (˜700-1400 nm) wavelengths. In some embodiments, the laser diode may emit blue or green light at wavelengths ranging from about 400 nm to about 670 nm.

It is to be understood that the embodiments disclosed with respect to sealed devices 200 (comprising QD/LED) can be incorporated into sealed devices 500 (comprising LD) without limitation. For example, the first glass substrate 501 and second inorganic substrate 507 can be chosen from similar materials and can have similar properties as those disclosed above for substrates 201 and 207 in FIGS. 2A-B, respectively. Similarly, the seal 511 can be formed in a manner similar to that described for seal 211 above, using similar sealing layers 315, 415 and patterns as described with respect to FIGS. 3-4 above. Furthermore, the cavity 509 can have a shape and properties similar to that of cavity 209 depicted in and described with reference to FIGS. 2A-B.

Further disclosed herein are sealed devices comprising a glass substrate comprising a first surface, a doped inorganic substrate comprising a second surface; and at least one seal bonding the glass substrate to the doped inorganic substrate, wherein the doped inorganic substrate comprises a thermal conductivity of greater than about 2.5 W/m-K and at least about 0.05 wt % of at least one dopant chosen from ZnO, SnO, SnO₂, or TiO₂. In some embodiments, the glass substrate may be bonded directly to the inorganic substrate or may be bonded by way of a sealing layer.

Referring to FIG. 6, an exemplary sealed device 600 can comprise a glass substrate 601 and a doped inorganic substrate 607 sealed together via seal 611. Although not depicted, one or both of the first or second substrates can comprise at least one cavity. The at least one cavity can comprise any suitable workpiece including, but not limited to, quantum dots, LEDs, laser diodes, or any other light emitting device. For instance, the sealed device 600 can comprise a cavity including at least one quantum dot and at least one LED as depicted in FIG. 2A-B, or a laser diode as depicted in FIG. 5, and so forth.

It is to be understood that the embodiments disclosed with respect to sealed devices 200 (comprising QD/LED) and 500 can be incorporated into sealed devices 600 without limitation. For example, the first glass substrate 601 and second inorganic substrate 607 can be chosen from similar materials and can have similar properties as those disclosed above for substrates 201 and 207 in FIGS. 2A-B, respectively. For example, the doped inorganic substrate 607 can comprise an inorganic substrate having a thermal conductivity of at least about 2.5 W/m-K and doped (e.g., at least about 0.05 wt %) with at least one dopant capable of absorbing light at a predetermined wavelength, such as the predetermined operating wavelength of a laser. Suitable dopants can include, for example, ZnO, SnO, SnO₂, TiO₂, and the like. In some embodiments, the dopant can be chosen from compounds absorbing at UV wavelengths (200-400 nm).

Similarly, the seal 611 can be formed in a manner similar to that described for seal 211 above, using similar sealing layers 315, 415 and patterns as described with respect to FIGS. 3-4 above. In additional embodiments, the seal 611 can be formed directly between the glass substrate and the doped inorganic substrate, e.g., due to absorption of the at least one dopant at the laser operating wavelength, as discussed in more detail with respect to the methods below. Furthermore, the substrates 601, 607 can comprise one or more cavities having a shape and properties similar to that of cavity 209 depicted in and described with reference to FIGS. 2A-B, and containing workpieces as depicted, for example, in FIGS. 2A-B or FIG. 5.

Methods

Disclosed herein are methods for making sealed devices, the methods comprising placing at least one quantum dot and at least one LED component in at least one cavity on a first surface of a glass substrate or a second surface of an inorganic substrate; positioning a sealing layer over at least a portion of the first surface or at least a portion of the second surface; bringing the first surface into contact with the second surface with the sealing layer positioned therebetween to form a sealing interface; and directing a laser beam operating at a predetermined wavelength onto the sealing interface to form a seal between the glass substrate and the inorganic substrate, the seal extending around the at least one cavity containing the at least one quantum dot and the at least one LED component, wherein the inorganic substrate has a thermal conductivity of greater than about 2.5 W/m-K.

Also disclosed herein are methods of making a sealed device comprising a laser diode, the methods comprising placing at least one laser diode in at least one cavity on a first surface of a glass substrate or a second surface of an inorganic substrate; positioning a sealing layer over at least a portion of the first surface or at least a portion of the second surface; bringing the first surface into contact with the second surface with the sealing layer positioned therebetween to form a sealing interface; and directing a laser beam operating at a predetermined wavelength onto the sealing interface to form a seal between the glass substrate and the inorganic substrate, the seal extending around the at least one cavity containing the at least one laser diode, wherein the inorganic substrate has a thermal conductivity of greater than about 2.5 W/m-K.

Further disclosed herein are method for making a sealed device, the methods comprising doping an inorganic substrate with at least one dopant absorbing at a predetermined wavelength; bringing a first surface of a glass substrate into contact with a second surface of the inorganic substrate to form a sealing interface; and directing a laser beam operating at the predetermined wavelength onto the sealing interface to form a seal between the glass substrate and the inorganic substrate, wherein the inorganic substrate has a thermal conductivity greater than about 2.5 W/m-K.

Still further disclosed herein are methods for making a sealed device, the methods comprising bringing a first surface of a glass substrate and a second surface of an inorganic substrate into contact with a sealing layer to form a sealing interface; and directing a laser beam operating at a predetermined wavelength onto the sealing interface to form a seal between the glass substrate and the inorganic substrate, wherein a difference between the CTE of the glass substrate and the CTE of the inorganic substrate is less than about 20×10⁻⁷/° C., and wherein the inorganic substrate has a thermal conductivity of greater than about 2.5 W/m-K.

According to various embodiments, a sealing layer can optionally be applied to at least a portion of the glass substrate or at least a portion of the inorganic substrate prior to sealing. As discussed above, the first (glass) or second (inorganic) substrate may comprise at least one cavity. Cavities can be provided in the first or second substrates, e.g., by pressing, molding, cutting, or any other suitable method. The sealing layer, if present, can be applied over any such cavity, or can be framed around the cavity. In some embodiments, at least one quantum dot and at least one LED component can be placed in the cavity. In alternative embodiments, at least one laser diode can be placed in the cavity. In further embodiments, a workpiece can be placed in the cavity.

According to various embodiments, the inorganic substrate may be a doped inorganic substrate. Doping can be carried out, for instance, during formation of the inorganic substrate, e.g., at least one dopant or precursor thereof can be added to the batch materials used to form the inorganic substrate. Suitable dopants can include, for example, ZnO, SnO, SnO₂, TiO₂, and the like. Exemplary dopant concentrations may include, for instance, greater than about 0.05 wt % (e.g., greater than about 1, 2, 3, 4, 5, 6, 7, 8, 9, or 10 wt %, and so on).

The first surface and second surface can then be brought into contact, optionally with the sealing layer positioned therebetween, to form a sealing interface. The substrates thus contacted can be sealed, e.g., around at least one cavity. According to various non-limiting embodiments, sealing can be carried out by laser welding. For example, a laser can be directed at or on a sealing interface such that the sealing layer absorbs the laser energy and heats the interface to a temperature near the T_{g} of the glass substrate. Melting of the sealing layer and/or glass substrate can thus form a bond between the first and second substrates. Alternatively, a sealing layer may not be present and the second inorganic substrate may be doped such that it absorbs the laser energy and heats the interface to a temperature near the T_{g} of the glass substrate. In various embodiments, laser sealing can be carried out at temperatures at or near room temperature, such as from about 25° C. to about 50° C., or from about 30° C. to about 40° C., including all ranges and subranges therebetween. While heating at the sealing interface may cause a temperature increase exceeding these temperatures, such heating is localized at the sealing region, thus decreasing the risk of damage to any heat-sensitive work pieces to be encapsulated in the device.

The laser may be chosen from any suitable laser known in the art for glass substrate welding. For example, the laser may emit light at UV (˜200-400 nm), visible (˜400-700 nm), or infrared (˜700-1600 nm) wavelengths. According to various embodiments, the laser may operate at a predetermined wavelength ranging from about 300 nm to about 1600 nm, such as from about 350 nm to about 1400 nm, from about 400 nm to about 1000 nm, from about 450 nm to about 750 nm, from about 500 nm to about 700 nm, or from about 600 nm to about 650 nm, including all ranges and subranges therebetween. In certain embodiments, the laser may be a UV laser operating at about 355 nm, a visible light laser operating at about 532 nm, or a near-infrared laser operating at about 810 nm, or any other suitable NIR wavelength. According to additional embodiments, the laser operating wavelength may be chosen as any wavelength at which the first glass substrate is substantially transparent and the sealing layer and/or inorganic substrate is absorbing. Exemplary lasers include IR lasers, argon ion beam lasers, helium-cadmium lasers, and third-harmonic generating lasers, to name a few.

In certain embodiments, the laser beam can have an average power ranging from about 0.2 W to about 50 W, such as from about 0.5 W to about 40 W, from about 1 W to about 30 W, from about 2 W to about 25 W, from about 3 W to about 20 W, from about 4 W to about 15 W, from about 5 W to about 12 W, from about 6 W to about 10 W, or from about 7 W to about 8 W, including all ranges and subranges therebetween. The laser may operate at any frequency and may, in certain embodiments, operate in a pulsed, modulated (quasi-continuous), or continuous manner. In some embodiments, the laser may operate in burst mode, each burst comprising a plurality of individual pulses. In some non-limiting embodiments, the laser may have a repetition rate ranging from about 1 kHz to about 1 MHz, such as from about 5 kHz to about 900 kHz, from about 10 kHz to about 800 kHz, from about 20 kHz to about 700 kHz, from about 30 kHz to about 600 kHz, from about 40 kHz to about 500 kHz, from about 50 kHz to about 400 kHz, from about 60 kHz to about 300 kHz, from about 70 kHz to about 200 kHz, or from about 80 kHz to about 100 kHz, including all ranges and subranges therebetween.

According to various embodiments, the beam may be directed at and focused on the sealing interface, below the sealing interface, or above the sealing interface. The beam spot diameter on the interface may be less than about 1 mm in some non-limiting embodiments. For example, the beam spot diameter may be less than about 500 microns, such as less than about 400 microns, less than about 300 microns, or less than about 200 microns, less than about 100 microns, less than 50 microns, or less than 20 microns, including all ranges and subranges therebetween. In some embodiments, the beam spot diameter may range from about 10 microns to about 500 microns, such as from about 50 microns to about 250 microns, from about 75 microns to about 200 microns, or from about 100 microns to about 150 microns, including all ranges and subranges therebetween.

According to various embodiments, sealing the substrate can comprise scanning or translating a laser beam along the substrates (or the substrates can be translated relative to the laser) using any predetermined path to produce any pattern, such as a square, rectangular, circular, oval, or any other suitable pattern or shape, for example, to hermetically seal at least one cavity in the device. The translation speed at which the laser beam (or substrate) moves along the interface may vary by application and may depend, for example, upon the composition of the first and second substrates and/or the focal configuration and/or the laser power, frequency, and/or wavelength. In certain embodiments, the laser may have a translation speed ranging from about 1 mm/s to about 1000 mm/s, for example, from about 5 mm/s to about 750 mm/s, from about 10 mm/s to about 500 mm/s, or from about 50 mm/s to about 250 mm/s, such as greater than about 100 mm/s, greater than about 200 mm/s, greater than about 300 mm/s, greater than about 400 mm/s, greater than about 500 mm/s, or greater than about 600 mm/s, including all ranges and subranges therebetween.

According to various embodiments disclosed herein, the laser wavelength, pulse duration, repetition rate, average power, focusing conditions, and other relevant parameters may be varied so as to produce energy sufficient to weld the first and second substrates together by way of the sealing layer. It is within the ability of one skilled in the art to vary these parameters as necessary for a desired application. In various embodiments, the laser fluence (or intensity) is below the damage threshold of the first and/or second substrate, e.g., the laser operates under conditions intense enough to weld the substrates together, but not so intense as to damage the substrates. In certain embodiments, the laser beam may operate at a translation speed that is less than or equal to the product of the diameter of the laser beam at the sealing interface and the repetition rate of the laser beam.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. Thus, for example, reference to “a cavity” includes examples having one such “cavity” or two or more such “cavities” unless the context clearly indicates otherwise. Similarly, a “plurality” or an “array” is intended to denote two or more, such that an “array of cavities” or a “plurality of cavities” denotes two or more such cavities.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

All numerical values expressed herein are to be interpreted as including “about,” whether or not so stated, unless expressly indicated otherwise. It is further understood, however, that each numerical value recited is precisely contemplated as well, regardless of whether it is expressed as “about” that value. Thus, “a dimension less than 10 mm” and “a dimension less than about 10 mm” both include embodiments of “a dimension less than about 10 mm” as well as “a dimension less than 10 mm.”

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a method comprising A+B+C include embodiments where a method consists of A+B+C, and embodiments where a method consists essentially of A+B+C.

It will be apparent to those skilled in the art that various modifications and variations can be made to the present disclosure without departing from the spirit and scope of the disclosure. Since modifications combinations, sub-combinations and variations of the disclosed embodiments incorporating the spirit and substance of the disclosure may occur to persons skilled in the art, the disclosure should be construed to include everything within the scope of the appended claims and their equivalents.

1-55. (canceled)

56. A sealed device comprising:
a glass substrate comprising a first surface;
an inorganic substrate comprising a second surface;
a sealing layer in contact with at least a portion of the first surface and at least a portion of the second surface;
at least one seal bonding the glass substrate to the inorganic substrate via the sealing layer;
wherein the inorganic substrate has a thermal conductivity of greater than about 2.5 W/m-K,
wherein at least one of the first or second surfaces comprises at least one cavity containing at least one quantum dot and at least one LED component or wherein at least one of the first or second surfaces comprises at least one cavity containing at least one laser diode, and
wherein the at least one seal extends around the at least one cavity.

57. The sealed device of claim 56, wherein the glass substrate comprises a glass chosen from aluminosilicate, alkali-aluminosilicate, borosilicate, alkali-borosilicate, aluminoborosilicate, and alkali-aluminoborosilicate glasses.

58. The sealed device of claim 56, wherein the inorganic substrate comprises aluminum nitride, aluminum oxide, beryllium oxide, boron nitride, or silicon carbide.

59. The sealed device of claim 56, wherein the sealing layer comprises a glass chosen from tin fluorophosphate glasses, tungsten-doped tin fluorophosphate glasses, chalcogenide glasses, tellurite glasses, borate glasses, and phosphate glasses.

60. The sealed device of claim 56, wherein the at least one seal is a laser weld seal.

61. The sealed device of claim 56, wherein the sealing layer is positioned over the at least one cavity, and wherein the sealing layer has an absorption of greater than about 10% at a predetermined laser wavelength and is substantially transparent at visible wavelengths.

62. The sealed device of claim 56, wherein the at least one quantum dot and the at least one LED component are in direct contact within the at least one cavity.

63. The sealed device of claim 56, wherein the at least one quantum dot and the at least one LED component are separated by a separation barrier within the at least one cavity.

64. A display device or optical device comprising the sealed device of claim 56.

65. A sealed device comprising:
a glass substrate comprising a first surface;
a doped inorganic substrate comprising a second surface; and
at least one seal bonding the glass substrate to the doped inorganic substrate,
wherein the doped inorganic substrate comprises a thermal conductivity of greater than 2.5 W/m-K and at least about 0.05 wt % of at least one dopant chosen from ZnO, SnO, SnO₂, or TiO₂.

66. The sealed device of claim 65, wherein the at least one seal comprises a glass-doped inorganic laser weld seal.

67. The sealed device of claim 65, further comprising at least one sealing layer positioned between the glass substrate and the doped inorganic substrate, and wherein the at least one seal comprises a glass-sealing layer-doped inorganic laser weld seal.

68. The sealed device of claim 65, wherein at least one of the first or second surfaces comprises at least one cavity, and wherein the at least one cavity contains at least one quantum dot and at least one LED component or at least one laser diode.

69. A sealed device comprising:
a first glass substrate comprising a first surface;
a second glass substrate comprising a second surface;
an inorganic substrate comprising a third surface;
a sealing layer in contact with at least a portion of the second surface and at least a portion of the third surface;
at least one seal bonding the second glass substrate to the inorganic substrate via the sealing layer;
wherein the inorganic substrate has a thermal conductivity of greater than about 2.5 W/m-K,
wherein at least one of the second or third surfaces comprises at least one cavity containing at least one quantum dot and at least one LED component, and
wherein the at least one seal extends around the at least one cavity.

70. The sealed device of claim 69, wherein the at least one LED component is contained in a first cavity and the at least one quantum dot is contained in a second cavity independent of the first cavity.

71. A sealed device comprising:
a first glass substrate comprising a first surface;
a second glass substrate comprising a second surface;
a third substrate comprising a third surface;
a first seal bonding the first glass substrate to the second glass substrate;
wherein at least one of the second or third surfaces comprises at least one cavity containing at least one quantum dot and at least one LED component, and
wherein the at least one seal extends around the at least one cavity.

72. The sealed device of claim 71, wherein the at least one LED component is contained in a first cavity and the at least one quantum dot is contained in a second cavity independent of the first cavity.

73. A sealed device comprising:
a first glass substrate comprising a first surface;
a second glass substrate comprising a second surface;
a third substrate comprising a third surface;
a first seal bonding the first glass substrate to the second glass substrate;
wherein at least one of the first or second surfaces comprises at least one cavity containing at least one quantum dot and wherein the third surface is adjacent to at least one LED component, and
wherein the at least one seal extends around the at least one cavity.

74. The sealed device of claim 73, further comprising one or more films to filter predetermined wavelengths of light, wherein the one or more films comprises alternating films of high refractive index material and low refractive index material.

75. The sealed device of claim 74, wherein the high refractive index material is selected from the group consisting of Nb₂O₅, Ta₂O₅, TiO₂, and compound oxides thereof, and wherein the low refractive index material is selected from the group consisting of SiO₂, ZrO₂, HfO₂, Bi₂O₃, La₂O₃, Al₂O₃, and compound oxides thereof.
